(19) United States
(12) Patent Application Publication
(10) Pub. No.: US 2014/0061611 A1
(43) Pub. Date: Mar. 6, 2014

(54) LIGHT SOURCE MODULE

(71) Applicant: Ultimate Image Corporation, Miaoli County (TW)

(72) Inventor: Chih-Feng SUNG, Miaoli County (TW)

(73) Assignee: Ultimate Image Corporation, Miaoli County (TW)

(21) Appl. No.: 13/974,268

(22) Filed: Aug. 23, 2013

(30) Foreign Application Priority Data
Sep. 3, 2012 (TW) 101132080

(51) Int. Cl. H01L 51/52

(52) U.S. Cl. CPC H01L 51/52
USPC 257/40

(57) ABSTRACT

A light source module, including a first electrode, a second electrode, a first light-emitting unit and a second light-emitting unit, is provided. The first light-emitting unit and the second light-emitting unit both are electrically connected between the first electrode and the second electrode and are configured to emit a light by a driving of a voltage signal formed between the first electrode and the second electrode. A first light-emitting area of the first light-emitting unit has an area size different to that of a second light-emitting area of the second light-emitting unit. The first light-emitting unit is configured to emit a light with a first spectrum, and the second light-emitting unit is configured to emit a light with a second spectrum.

### FIELD OF THE INVENTION

The present invention relates to a structure of a light source module, and more particularly to a structure of a light source module of an organic light-emitting diode configured to emit a white light and used in lighting apparatus.

### BACKGROUND OF THE INVENTION

Basically, the layer structures of conventional white organic light-emitting diode (OLED) modules may be categorized into three types. In the first type as shown in FIG. 1A, the layer structure 100a is structured by sequentially stacking layers of red OLED film 110a, green OLED film 120a and blue OLED film 130a on a transparent electrode 140. In the second type as shown in FIG. 1B, the layer structure 100b is structured by sequentially stacking a plurality of layer groups on the transparent electrode 140; wherein one exemplary layer group includes a red OLED film 110a, a green OLED film 120a and a blue OLED film 130a, and another exemplary layer group includes a red OLED film 110b, a green OLED film 120b and a blue OLED film 130b. In the third type as shown in FIG. 1C, the layer structure 100c is structured by disposing each one of the red OLED film 110a, green OLED film 120a and blue OLED film 130a disposed on the transparent electrode 140.

Generally, the lighting apparatus having a white OLED module equipped with the third type of layer structure has a preferred luminous efficiency. However, the red OLED, green OLED and blue OLED each have respective different voltage-luminance characteristics. If being configured to emit a specific white light, the white OLED module may need to employ additional driver circuits and integrated circuit devices to provide different voltages for the driving of the red OLED, green OLED and blue OLED. Correspondingly, additional manufacturing processes are also required for the various indium tin oxide (ITO) electrodes used by the red OLED, green OLED and blue OLED, and consequentially manufacturing cost increases.

Thus, to solve the aforementioned problems, there is a need to provide a new white OLED module having a simplified manufacturing process and a lower manufacturing cost.

### SUMMARY OF THE INVENTION

The present invention provides a light source module to achieve a purpose of simplifying manufacturing process and reducing manufacturing cost by adjusting light-emitting areas of different light-emitting units to make the light source module emit a specific white light.

In order to achieve the aforementioned or other advantages, the present invention provides a light source module, including a first electrode, a second electrode, a first light-emitting unit and a second light-emitting unit. The first light-emitting unit and the second light-emitting unit both are electrically connected between the first electrode and the second electrode and are configured to emit a light by a driving of a voltage signal formed between the first electrode and the second electrode; wherein a first light-emitting area of the first light-emitting unit has an area size different to that of a second light-emitting area of the second light-emitting unit, and the first light-emitting unit is configured to emit a light with a first spectrum, the second light-emitting unit is configured to emit a light with a second spectrum.

In an embodiment, the aforementioned first light-emitting unit and the second light-emitting unit are organic light-emitting diodes.

In an embodiment, the aforementioned first spectrum is a blue-light spectrum, the second spectrum is a yellow-light spectrum of, and the first light-emitting area has an area size greater than that of the second light-emitting area.

In an embodiment, the light source module further includes at least an insulating structure disposed between the first light-emitting unit and the second light-emitting unit as well as between the second electrode corresponding to the first light-emitting unit and the second electrode corresponding to the second light-emitting unit.

In an embodiment, the light source module further includes a third light-emitting unit electrically connected between the first electrode and the second electrode and configured to emit a light by a driving of the voltage signal formed between the first electrode and the second electrode, wherein a third light-emitting area of the third light-emitting unit has an area size different to that of the first light-emitting area and the second light-emitting area, and the third light-emitting unit is configured to emit a light with a third spectrum.

In an embodiment, the aforementioned third light-emitting unit is an organic light-emitting diode.

In an embodiment, the aforementioned first spectrum is a blue-light spectrum, the second spectrum is a green-light spectrum, the third spectrum is a red-light spectrum, and the third light-emitting area has an area size greater than that of the first light-emitting area, the first light-emitting area has an area size greater than that of the second light-emitting area.

In an embodiment, the light source module further includes a plurality of insulating structures, wherein the insulating structures are disposed between the first light-emitting unit and the second light-emitting unit and between the second light-emitting unit and the third light-emitting unit, respectively, wherein the insulating structures are further disposed between the second electrode corresponding to the first light-emitting unit and the second electrode corresponding to the second light-emitting unit and between the second electrode corresponding to the second light-emitting unit and the second electrode corresponding to the third light-emitting unit.

In an embodiment, the aforementioned first electrode has a material of Indium Tin Oxide (ITO), the second electrode has a material of a metal with a low work function.

In an embodiment, the aforementioned first electrode is an anode and the second electrode is a cathode.

In summary, by adjusting the light-emitting areas of the red OLED, green OLED and blue OLED, or the light-emitting areas of the yellow OLED and blue OLED and applying the same voltage signal on each one of the various light-emitting units, the light source module provided by the present invention and used in a lighting apparatus is able to emit a specific white light. Thus, compared with the conventional white OLED lighting module having a complicated circuit design with driving circuits and integrated circuit devices, an object of providing a light source module having a simplified manufacturing process and lower manufacturing cost is achieved.

For making the above and other purposes, features and benefits become more readily apparent to those ordinarily skilled in the art, the preferred embodiments and the detailed descriptions with accompanying drawings will be put forward in the following descriptions.

### BRIEF DESCRIPTION OF THE DRAWINGS

The present invention will become more readily apparent to those ordinarily skilled in the art after reviewing the following detailed description and accompanying drawings, in which:

FIG. 1A is a schematic diagram illustrating a layer structure of a conventional white OLED module;

FIG. 1B is a schematic diagram illustrating another layer structure of a conventional white OLED module;

FIG. 1C is a schematic diagram illustrating still another layer structure of a conventional white OLED module;

FIG. 2 is a schematic diagram illustrating a structure of a light source module in accordance with an embodiment of the present invention; and

FIG. 3 is a schematic diagram illustrating a structure of a light source module in accordance with another embodiment of the present invention.

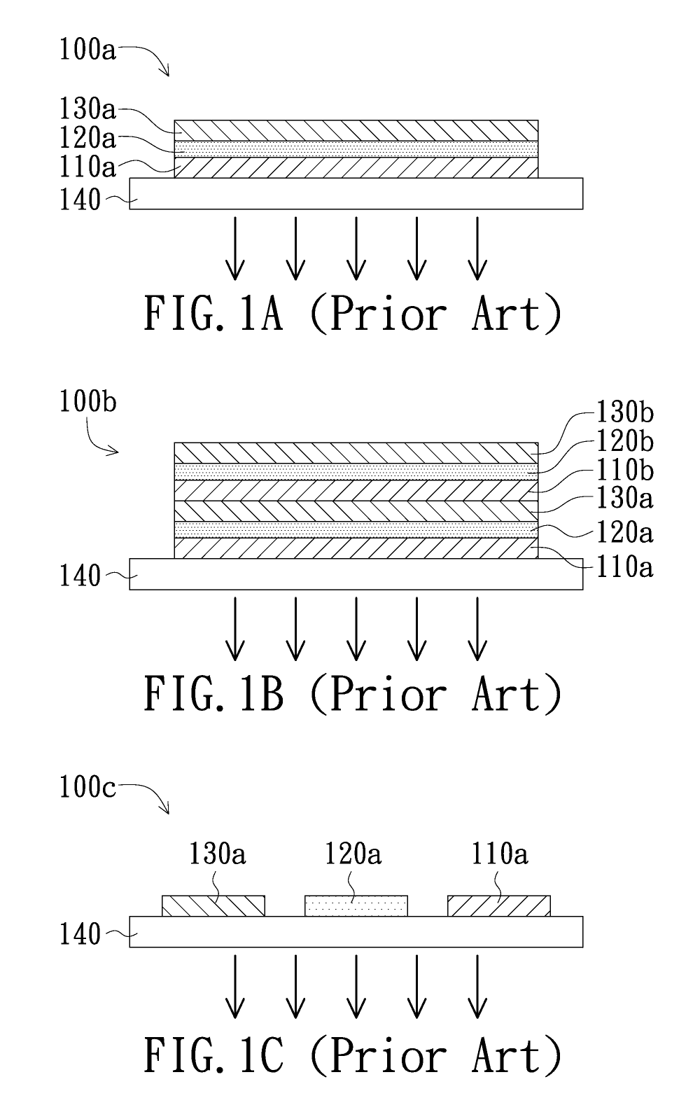

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

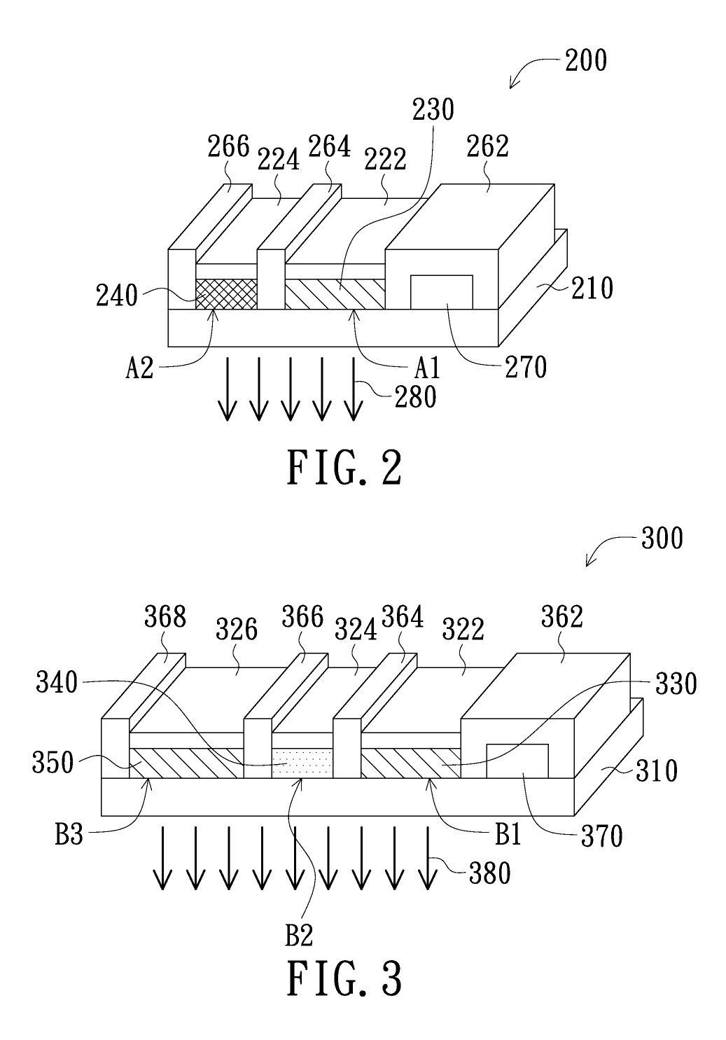

FIG. 2 is a schematic diagram illustrating a structure of a light source module in accordance with an embodiment of the present invention. As shown, the light source module 200 in this embodiment of the present invention includes a first electrode 210, second electrodes 222, 224, a first light-emitting unit 230, a second light-emitting unit 240, at least one insulating structure (herein the light source module 200 is exemplified by including three insulating structures 262, 264 and 266) and an auxiliary electrode 270. In addition, the first light-emitting unit 230 and the second light-emitting unit 240 both are, for example, an organic light-emitting diode.

Specifically, the first light-emitting unit 230 is electrically connected between the first electrode 210 and the second electrode 222. The second light-emitting unit 240 is electrically connected between the first electrode 210 and the second electrode 224. The first light-emitting unit 230 and the second light-emitting unit 240 are configured to emit light 280 by a driving of the same voltage signal formed between the first electrode 210 and the second electrodes 222, 224, respectively. The first light-emitting unit 230 has a first light-emitting area A1, which has an area size different to a second light-emitting area A2 of the second light-emitting unit 240; wherein the first light-emitting area A1 has an area size greater than that of the second light-emitting area A2, for example. The first light-emitting unit 230 is configured to emit a light with a first spectrum, and the second light-emitting unit 240 is configured to emit a light with a second spectrum. In this embodiment, the first spectrum is a blue-light spectrum which has wavelengths mainly located between 430-500 nm; and the second spectrum is a yellow-light spectrum which has wavelengths mainly located between 570-640 nm.

In this embodiment, it is to be noted that the light source module 200 is able to emit a specific white light 280 by adjusting a relative ratio of the first light-emitting area A1 of the first light-emitting unit 230 to the second light-emitting area A2 of the second light-emitting unit 240 and applying the same driving voltage to the first light-emitting unit 230 and the second light-emitting unit 240 through connecting the first electrode 210 and the second electrodes 222, 224 to the same power supply unit. Thus, due to no need of additional specific driving circuit devices and manufacturing process in response to the voltage-luminance characteristics of various colors of OLED units, the light source module of the present invention has a simplified manufacturing process and lower manufacturing costs. Furthermore, it is understood that the light source module 200 of the present invention can be applied to a lighting apparatus.

As shown in FIG. 2, the insulating structure 264 is disposed between the first light-emitting unit 230 and the second light-emitting unit 240 as well as between the second electrode 222 corresponding to the first light-emitting unit 230 and the second electrode 224 corresponding to the second light-emitting unit 240. Accordingly, the second electrode 222 has an area size greater than that of the second electrode 224 if the first light-emitting area A1 has an area size greater than that of the second light-emitting area A2.

As shown in FIG. 2, the auxiliary electrode 270 is disposed on a side of the first light-emitting unit 230 away from the second light-emitting unit 240. One part of the insulating structure 262 is disposed between the auxiliary electrode 270 and the first light-emitting unit 230 as well as the second electrode 222, another part of the insulating structure 262 is disposed on a side of the auxiliary electrode 270 away from the first electrode 210; and still another part of the insulating structure 262 is disposed on another side of the auxiliary electrode 270 away from the first light-emitting unit 230. The insulating structure 266 is disposed on a side of the second light-emitting unit 240 away from the first light-emitting unit 230.

The first electrode 210 has, for example, a material of indium tin oxide. The second electrode 222, 224 has, for example, a material of metals with low work function. The first electrode 210 is an anode and the second electrodes 222, 224 are cathodes, for example.

FIG. 3 is a schematic diagram illustrating a structure of a light source module in accordance with another embodiment of the present invention. As shown, the light source module 300 in this embodiment of the present invention includes a first electrode 310, second electrodes 322, 324 and 326, a first light-emitting unit 330, a second light-emitting unit 340, a third light-emitting unit 350, a plurality of insulating structures 362, 364, 366 and 368, and a auxiliary electrode 370. The first light-emitting unit 330, the second light-emitting unit 340 and the third light-emitting unit 350 are organic light-emitting diodes (OLEDs), for example.

Specifically, the first light-emitting unit 330 is electrically connected between the first electrode 310 and the second electrode 322; the second light-emitting unit 340 is electrically connected between the first electrode 310 and the second electrode 324; and the third light-emitting unit 350 is electrically connected between the first electrode 310 and the second electrode 326. The first light-emitting unit 330, the second light-emitting unit 340, and the third light-emitting unit 350 are configured to emit lights 380 by a driving of the same voltage signal formed between the first electrode 310 and the second electrodes 322, 324 and 326, respectively. The first light-emitting unit 330 has a first light-emitting area B1; the second light-emitting unit 340 has a second light-emitting area B2; the third light-emitting unit 350 has a third light-emitting area B3; wherein the first light-emitting area B1, second light-emitting area B2 and third light-emitting area B3 have area sizes different to one another. For example, the third light-emitting area B3 has an area size greater than that of the first light-emitting area B1; and the first light-emitting area B1 has an area size greater than that of the second light-emitting area B2 (that is, B3>B1>B2). The first light-emitting unit 330 is configured to emit a light with a first spectrum; the second light-emitting unit 340 is configured to emit a light with a second spectrum; and the third light-emitting unit 350 is configured to emit a light with a third spectrum, for example. In this embodiment, the first spectrum is a blue-light spectrum; the second spectrum is a green-light spectrum; and the third spectrum is a red-light spectrum. In this embodiment, it is to be noted that the light source module 300 is able to emit a specific white light 380 by adjusting a relative ratio of the first light-emitting area B1 of blue light to the second light-emitting area B2 of green light to the third-emitting area B3 of red light and applying the same driving voltage to the first light-emitting unit 330 (the blue OLED), the second light-emitting unit 340 (the green OLED) and the third light-emitting unit 350 (the red OLED). Furthermore, it is understood that the light source module 300 can be applied in a lighting apparatus.

The insulating structure 364 is disposed between the first light-emitting unit 330 and the second light-emitting unit 340 as well as between the second electrode 322 and the second electrode 324. The insulating structure 366 is disposed between the second light-emitting unit 340 and the third light-emitting unit 350 as well as between the second electrode 324 and the second electrode 326. Accordingly, the second electrode 326 has an area size greater than that of the second electrode 322 and the second electrode 322 has an area size greater than that of the second electrode 324 if B3>B1>B2.

As shown in FIG. 3, the insulating structure 368 is disposed on a side of the third light-emitting unit 350 away from the second light-emitting unit 340. The relative position of the auxiliary electrode 370 to the insulating structure 362 in this embodiment is similar to that of the auxiliary electrode 270 to the insulating structure 262 in the aforementioned embodiment shown in FIG. 2; the materials and polarities of the first electrode 310 and the second electrodes 322, 324 and 326 of the light source module 300 in this embodiment are similar to that of the first electrode 210 and the second electrodes 222, 224 in the aforementioned embodiment shown in FIG. 2; thus, no redundant detail is to be given herein.

In summary, by adjusting the light-emitting areas of the red OLED, green OLED and blue OLED or the light-emitting areas of the yellow OLED and blue OLED and applying the same voltage signal on each one of the various light-emitting units, the light source module provided by the present invention and used in a lighting apparatus is able to emit a specific white light. Thus, compared with the conventional white OLED lighting module having a complicated circuit design with driving circuits and integrated circuit devices, an object of providing a light source module having a simplified manufacturing process and lower manufacturing cost is achieved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A light source module, comprising:
a first electrode;
a second electrode; and
a first light-emitting unit; and
a second light-emitting unit,
wherein the first light-emitting unit and the second light-emitting unit both are electrically connected between the first electrode and the second electrode and are configured to emit a light by a driving of a voltage signal formed between the first electrode and the second electrode, wherein a first light-emitting area of the first light-emitting unit has an area size different to that of a second light-emitting area of the second light-emitting unit, the first light-emitting unit is configured to emit a light with a first spectrum, and the second light-emitting unit is configured to emit a light with a second spectrum.

2. The light source module according to claim 1, wherein the first light-emitting unit and the second light-emitting unit are organic light-emitting diodes.

3. The light source module according to claim 1, wherein the first spectrum is a blue-light spectrum, the second spectrum is a yellow-light spectrum, and the first light-emitting area has an area size greater than that of the second light-emitting area.

4. The light source module according to claim 1, further comprising at least an insulating structure disposed between the first light-emitting unit and the second light-emitting unit as well as between the second electrode corresponding to the first light-emitting unit and the second electrode corresponding to the second light-emitting unit.

5. The light source module according to claim 1, further comprising:
a third light-emitting unit electrically connected between the first electrode and the second electrode and configured to emit a light by a driving of the voltage signal formed between the first electrode and the second electrode, wherein a third light-emitting area of the third light-emitting unit has an area size different to that of the first light-emitting area and the second light-emitting area, and the third light-emitting unit is configured to emit a light with a third spectrum.

6. The light source module according to claim 5, wherein the third light-emitting unit is an organic light-emitting diode.

7. The light source module according to claim 5, wherein the first spectrum is a blue-light spectrum, the second spectrum is a green-light spectrum, the third spectrum is a red-light spectrum, and the third light-emitting area has an area size greater than that of the first light-emitting area, the first light-emitting area has an area size greater than that of the second light-emitting area.

8. The light source module according to claim 5, further comprising:
a plurality of insulating structures, wherein the insulating structures are disposed between the first light-emitting unit and the second light-emitting unit and between the second light-emitting unit and the third light-emitting unit, respectively, wherein the insulating structures are further disposed between the second electrode corresponding to the first light-emitting unit and the second electrode corresponding to the second light-emitting unit and between the second electrode corresponding to the second light-emitting unit and the second electrode corresponding to the third light-emitting unit.

9. The light source module according to claim 1, wherein the first electrode has a material of Indium Tin Oxide (ITO), the second electrode has a material of a metal with a low work function.

10. The light source module according to claim 1, wherein the first electrode is an anode and the second electrode is a cathode.
